(19) United States
(12) Patent Application Publication
(10) Pub. No.: US 2025/0140531 A1
(43) Pub. Date: May 1, 2025

(54) SUBSTRATE PROCESSING APPARATUS INCLUDING SUBSTRATE SUPPORT UNIT

(71) Applicant: SEMES CO., LTD., Cheonan-si (KR)

(72) Inventors: Sang Woo KIM, Cheonan-si (KR); Jae Kyung LEE, Cheonan-si (KR); Ju Yong JANG, Cheonan-si (KR)

(73) Assignee: SEMES CO., LTD., Cheonan-si (KR)

(21) Appl. No.: 18/826,134

(22) Filed: Sep. 5, 2024

(30) Foreign Application Priority Data
Oct. 26, 2023 (KR) 10-2023-0144924

(51) Int. Cl. H01J 37/32

(52) U.S. Cl. CPC H01J 37/32715; H01J 37/32449; H01J 2237/3321; H01J 2237/334

(57) ABSTRACT

Disclosed is a substrate processing apparatus including a substrate support unit. The substrate support unit supports a substrate, has at least one pin hole formed vertically therethrough, and accommodates a lift pin therein so as to allow the lift pin to ascend and descend through the pin hole. The substrate support unit includes a ceramic puck on which the substrate is seated, a base plate configured to support the ceramic puck, an adhesive layer for coupling between the ceramic puck and the base plate, and a bush provided around the pin hole. The bush includes a first bush having a tube shape and a second bush coupled to an outer peripheral surface of the first bush, and the first bush includes a protruding portion formed on an upper surface thereof.

### CROSS-REFERENCE TO RELATED APPLICATION(S)

This application claims priority under 35 U.S.C. § 119 to Korean Patent Application No. 10-2023-0144924, filed on Oct. 26, 2023 in the Korean Intellectual Property Office, the disclosure of which is incorporated by reference herein in its entirety.

### BACKGROUND OF THE INVENTION

### Field of the Invention

The present invention relates to a substrate processing apparatus including a substrate support unit. More particularly, the present: invention relates to a substrate processing apparatus including a substrate support unit capable of reducing an assembly tolerance of a bush provided in the substrate support unit.

### Description of the Related Art

In general, a process of manufacturing a semiconductor device includes a deposition process for forming a film on a semiconductor substrate, a chemical/mechanical polishing process for planarizing the film, a photoresist process for forming a photoresist pattern on the film, an etching process for etching the film using the photoresist pattern to form a pattern having electrical characteristics, an ion implantation process for implanting specific ions into predetermined regions of the substrate, a cleaning process for removing impurities from the substrate, and an inspection process for inspecting the surface of the substrate on which the film or pattern is formed.

Plasma may be used in some of the above processes. A substrate support unit for supporting a substrate may be provided in a chamber of a substrate processing apparatus using plasma. A substrate may be seated on the upper surface of the substrate support unit, and a lift pin for loading/unloading the substrate on/from the upper surface of the substrate support unit may be provided in the substrate support unit.

FIG. 1 is a view showing a bush provided in a conventional substrate support unit.

Referring to FIG. 1, the conventional substrate support unit 20 may include an electrostatic chuck 210, which includes a ceramic puck 212 and a base plate 214. The electrostatic chuck 210 may include an adhesive layer 216 to bond the ceramic puck 212 and the base plate 214 to each other. The substrate support unit 20 may include a pin hole 220 formed therein to allow a lift pin 232 to move vertically therethrough. The lift pin 232 may move vertically through the pin hole 220 in order to load and unload a substrate. A bush 24 is provided around the pin hole 220 in the substrate support unit 20.

Generally, the bush 24 includes a first bush 242, a second bush 244, and a bonding layer 246. The bush 24 is provided in a state of being bonded to the ceramic puck 212 in the substrate support unit 20. However, in the process of bonding the bush 24 and the ceramic puck 212 to each other, the bush 24 and the ceramic puck 212 may be misaligned from each other, which may cause an assembly tolerance between the bush 24 and the ceramic puck 212. In particular, while a process using plasma is performed, the plasma may enter the assembly tolerance portion, which may generate particles, leading to reduction in product yield.

In addition, when the lift pin 232 moves through the pin hole 220, the lift pin 232 may be damaged due to an assembly tolerance between the first bush 242 and the second bush 244.

### SUMMARY OF THE INVENTION

The present invention has been made to solve the above problems, and it is an object of the present invention to provide a substrate processing apparatus including a substrate support unit capable of reducing an assembly tolerance between a bush and a ceramic puck.

The objects to be accomplished by the invention are not limited to the above-mentioned object, and other objects not mentioned herein will be clearly understood by those skilled in the art from the following description.

In accordance with an aspect of the present invention, the above and other objects can be accomplished by the provision of a substrate support unit, which supports a substrate, has at least one pin hole formed vertically therethrough, and accommodates a lift pin therein so as to allow the lift pin to ascend and descend through the at least one pin hole, the substrate support unit including a ceramic puck configured to allow the substrate to be seated thereon, a base plate configured to support the ceramic puck, an adhesive layer for coupling between the ceramic puck and the base plate, and a bush provided around the at least one pin hole, wherein the bush includes a first bush having a tube shape and a second bush coupled to an outer peripheral surface of the first bush, and the first bush includes a protruding portion formed on an upper surface thereof.

In one embodiment, the protruding portion may protrude from the upper surface of the first bush to a predetermined height in the longitudinal direction of the first bush, and may be coupled to a concave portion formed in a lower surface of the ceramic puck.

In one embodiment, the substrate support unit may further include a bonding layer to couple the bush to the substrate support unit.

In one embodiment, the substrate support unit may further include a coating layer formed between the adhesive layer and the base plate.

In one embodiment, the second bush may be coupled to the base plate and the first bush in a state of being inserted into a recess formed in the base plate.

In one embodiment, the second bush may not be exposed to the at least one pin hole.

In one embodiment, the first bush may include a lower region and an upper region formed on the lower region, and the second bush may be coupled to the lower region of the first bush in a fit manner.

In one embodiment, the bonding layer may be formed on an upper surface of the first bush, an outer peripheral surface of the first bush, and an upper surface of the second bush coupled to the first bush.

In accordance with another aspect of the present invention, there is provided a substrate processing apparatus including a chamber having a processing space defined therein, a substrate support unit disposed in the processing space to support a substrate, the substrate support unit having at least one pin hole formed vertically therethrough and accommodating a lift pin therein so as to allow the lift pin to ascend and descend through the at least one pin hole, a gas supply unit configured to supply gas to the processing space, a plasma generation unit configured to convert the supplied gas into plasma, and a controller configured to control the gas supply unit and the plasma generation unit, wherein the substrate support unit includes a ceramic puck configured to allow the substrate to be seated thereon, a base plate configured to support the ceramic puck, an adhesive layer for coupling between the ceramic puck and the base plate, and a bush provided around the at least one pin hole, the bush includes a first bush having a tube shape and a second bush coupled to an outer peripheral surface of the first bush, and the first bush includes a protruding portion formed on an upper surface thereof.

In one embodiment, the protruding portion may protrude from the upper surface of the first bush to a predetermined height in the longitudinal direction of the first bush, and may be coupled to a concave portion formed in a lower surface of the ceramic puck.

In one embodiment, the substrate support unit may further include a bonding layer to couple the bush to the substrate support unit.

In one embodiment, the substrate processing apparatus may further include a coating layer formed between the adhesive layer and the base plate.

In one embodiment, the second bush may be coupled to the base plate and the first bush in a state of being inserted into a recess formed in the base plate.

In one embodiment, the second bush may not be exposed to the at least one pin hole.

In one embodiment, the bonding layer may be formed on an upper surface of the first bush, an outer peripheral surface of the first bush, and an upper surface of the second bush coupled to the first bush.

In accordance with still another aspect of the present invention, there is provided a substrate processing apparatus including a chamber having a processing space defined therein, a substrate support unit disposed in the processing space to support a substrate, the substrate support unit having at least one pin hole formed vertically therethrough and accommodating a lift pin therein so as to allow the lift pin to ascend and descend through the at least one pin hole, a gas supply unit configured to supply gas to the processing space, a plasma generation unit configured to convert the supplied gas into plasma, and a controller configured to control the gas supply unit and the plasma generation unit, wherein the substrate support unit includes a ceramic puck configured to allow the substrate to be seated thereon, a base plate configured to support the ceramic puck, an adhesive layer for coupling between the ceramic puck and the base plate, and a bush provided around the at least one pin hole, wherein the bush includes a first bush having a tube shape and coupled to the ceramic puck, the adhesive layer, and the base plate and a second bush coupled to an outer peripheral surface of the first bush and the base plate, the first bush includes a lower region, an upper region formed on the lower region, and a protruding portion formed on an upper surface of the upper region, and the first bush is integrally coupled to the ceramic puck in such a manner that the protruding portion is inserted into a concave portion formed in a lower surface of the ceramic puck.

In one embodiment, the substrate support unit may further include a bonding layer to couple the bush to the substrate support unit.

In one embodiment, the substrate processing apparatus may further include a coating layer formed between the adhesive layer and the base plate.

In one embodiment, the second bush may be coupled to the base plate and the first bush in a state of being inserted into a recess formed in the base plate.

In one embodiment, the second bush may have an annular ring shape, and may be coupled to an outer peripheral surface of the lower region of the first bush in a fit manner.

### BRIEF DESCRIPTION OF THE DRAWINGS

The above and other objects, features, and other advantages of the present invention will be more clearly understood from the following detailed description taken in conjunction with the accompanying drawings, in which:

FIG. 1 is a view showing a bush provided in a conventional substrate support unit;

FIG. 2 is a view showing a substrate processing apparatus according to an embodiment of the present invention;

FIG. 3 is a view showing a substrate support unit according to an embodiment of the present invention; and

FIG. 4 is a view showing a bush provided in the substrate support unit according to an embodiment of the present invention.

### DETAILED DESCRIPTION OF THE INVENTION

Hereinafter, embodiments of the present invention will be described in detail with reference to the accompanying drawings so that those skilled in the art can easily carry out the embodiments. The present invention may, however, be embodied in many different forms, and should not be construed as being limited to the embodiments set forth herein.

In the following description of the embodiments of the present invention, a detailed description of known functions or configurations incorporated herein will be omitted when it may unnecessarily obscure the subject matter of the present invention. Throughout the drawings, parts performing similar functions and operations are denoted by the same reference numerals.

At least some of the terms used in this specification are terms defined taking into consideration the functions obtained in accordance with the present invention, and may be changed in accordance with the intention of users or operators or usual practice. Therefore, the definitions of these terms should be determined based on the total content of this specification.

As used herein, singular forms may include plural forms, unless the context clearly indicates otherwise. Additionally, the term “comprise”, “include”, or “have” described herein should be interpreted not to exclude other elements but to further include such other elements unless mentioned otherwise.

In the drawings, the sizes or shapes of elements and thicknesses of lines may be exaggerated for clarity and convenience of description.

Hereinafter, embodiments of the present invention will be described in detail with reference to the accompanying drawings, and the same or similar elements are denoted by the same reference numerals even though they are depicted in different drawings, and redundant descriptions thereof will be omitted.

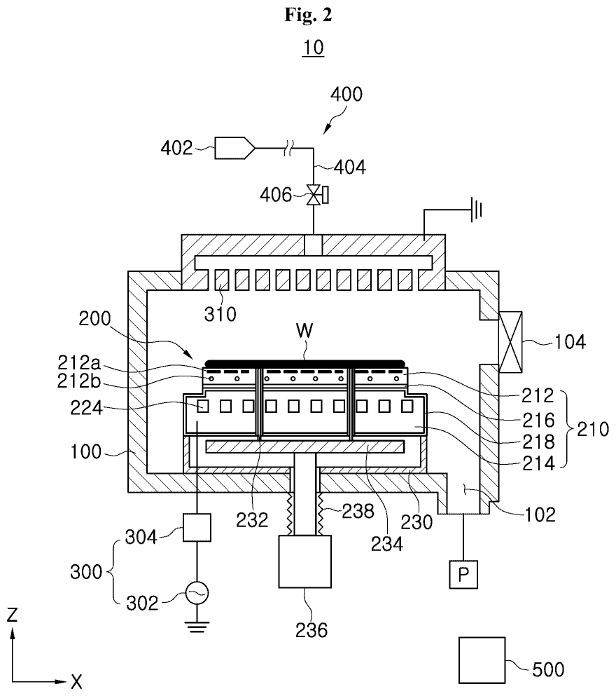

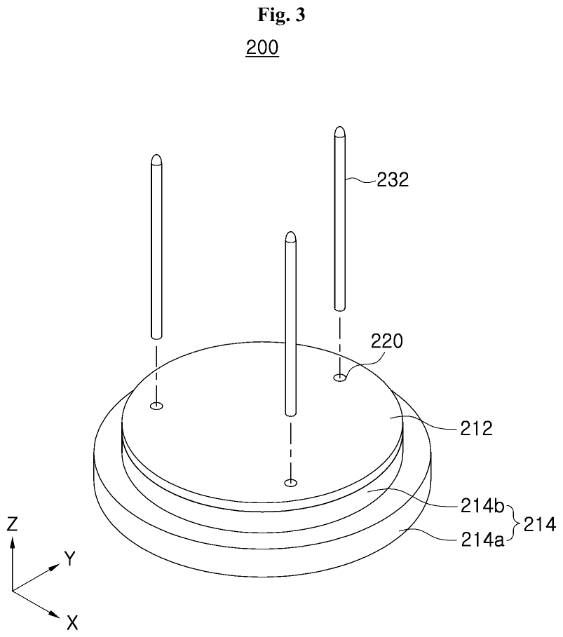

FIG. 2 is a view showing a substrate processing apparatus according to an embodiment of the present invention, and FIG. 3 is a view showing a substrate support unit according to an embodiment of the present invention.

Referring to FIGS. 2 and 3, the substrate processing apparatus 10 may include a chamber 100, a substrate support unit 200, a plasma generation unit 300, a gas supply unit 400, and a controller 500.

The chamber 100 may include a processing space defined therein to allow a plasma process to be performed therein. The chamber 100 may include an exhaust port 102 formed in a lower side thereof. The exhaust port 102 may be connected to an exhaust line on which a pump P is mounted. The exhaust port 102 may discharge reaction by-products generated during the plasma process and gas remaining in the chamber 100 to the outside of the chamber 100 through the exhaust line. In this case, pressure in the inner space in the chamber 100 may be reduced to a predetermined pressure.

The chamber 100 may include an opening 104 formed in the sidewall thereof. The opening 104 may function as a passage through which a substrate W is introduced into or removed from the chamber 100. The opening 104 may be configured to be opened and closed by a door assembly.

The substrate support unit 200 may be disposed in a lower area in the chamber 100. The substrate support unit 200 may support the substrate W using electrostatic force. However, this embodiment is not limited thereto. The substrate W may be supported in various ways, such as mechanical clamping or vacuum support.

In the case of supporting the substrate W using electrostatic force, the substrate support unit 200 may include an electrostatic chuck 210, which includes a ceramic puck 212 and a base plate 214.

The substrate W may be placed on the upper surface of the ceramic puck 212, and an electrode 212a and a heater 212b may be provided in the ceramic puck 212. The ceramic puck 212 may be made of a ceramic material, for example, quartz.

The base plate 214 may be provided under the ceramic puck 212. The base plate 214 may have a disc shape and may be made of metal. The base plate 214 may include a lower region 214a having a predetermined diameter and an upper region 214b having a smaller diameter than the lower region 214a. A cooling passage 224 may be formed in the lower region 214a of the base plate 214, and the upper region 214b of the base plate 214 may be coupled to the ceramic puck 212.

In addition, although not shown, a focus ring (not shown) for control of plasma on the peripheral portion of the substrate W and an edge ring (not shown) for preventing damage to the side surface of the electrostatic chuck 210 may be provided on a portion of the lower region 214a of the base plate 214 that protrudes beyond the upper region 214b of the base plate 214.

A coating layer 218 may be formed on the periphery of the base plate 214. The coating layer 218 may serve to prevent the base plate 214 from being exposed to plasma, and may have a predetermined thickness. The coating layer 218 may be alumina (Al₂O₃).

An adhesive layer 216 may be formed between the ceramic puck 212 and the base plate 214 in order to bond the ceramic puck 212 and the base plate 214 to each other.

A pedestal 230 may be provided under the base plate 214 in order to support the ceramic puck 212 and the base plate 214. The pedestal 230 may be formed in a cylindrical shape having a predetermined height, and may have a space defined therein. A lift pin support member 234 for supporting a lift pin 232 may be provided in the pedestal 230. The lift pin support member 234 may be raised and lowered by a lift pin driving unit 236.

The substrate support unit 200 may be provided with a plurality of lift pins 232 disposed at regular intervals in order to load and unload the substrate W. The substrate support unit 200 may include a plurality of pin holes 220 vertically penetrating the substrate support unit 200 to allow the lift pins 232 to move vertically therethrough. The substrate support unit 200 may be provided therein with a bush 240 disposed around each of the pin holes 220. The bush 240 may serve to reduce friction between the lift pin 232 and the substrate support unit 200 and to prevent damage to the lift pin 232 due to the friction. A detailed description of the bush 240 will be given later.

The lift pin 232 may be provided in plural, and each of the plurality of lift pins 232 may be received in a respective one of the pin holes 220 formed in the substrate support unit 200. The diameter of the lift pin 232 may be formed to be slightly smaller than the diameter of the pin hole 220.

The lift pins 232 may be inserted into and fixed in lift pin holders (not shown). The number of lift pin holders (not shown) may be identical to the number of lift pins 232, and the lift pin holders (not shown) may be coupled and fixed to the lift pin support member 234.

The lift pin support member 234 may be provided in the chamber 100, and may support the lift pins 232 and the lift pin holders (not shown). The lift pin support member 234 may be formed in a plate shape in order to support the plurality of lift pins 232 and the lift pin holders (not shown). However, this embodiment is not limited thereto. The lift pin support member 234 may be connected to the lift pin driving unit 236, and may be moved vertically by the lift pin driving unit 236.

The lift pin driving unit 236 may raise and lower the lift pin support member 234. Due to operation of the lift pin driving unit 236, the lift pin support member 234 may move vertically, and accordingly, the lift pins 232 may move along the pin holes 220. The lift pin driving unit 236 may be disposed outside the chamber 100. The lift pin driving unit 236 may employ a hydraulic cylinder, a pneumatic cylinder, or the like. However, this embodiment is not limited thereto. Although the embodiment of the present invention is described as including one lift pin driving unit 236, this embodiment is not limited thereto. The lift pin driving unit 236 may be provided in plural in order to raise and lower respective lift pins 232.

A bellows 238 may be provided between the lift pin driving unit 236 and the lower surface of the chamber 100. Due to the bellows 238, the inside of the chamber 100 may be blocked from the outside even when the lift pin support member 234 moves vertically.

The plasma generation unit 300 may generate plasma in the processing space in the chamber 100. Plasma may be generated in an area above the substrate support unit 200 in the chamber 100. According to the embodiment of the present invention, the plasma generation unit 300 may generate plasma in the processing space in the chamber 100 using a capacitively coupled plasma (CCP) source.

However, this embodiment is not limited thereto. The plasma generation unit 300 may also generate plasma in the processing space in the chamber 100 using another type of plasma source, such as an inductively coupled plasma (ICP) source or microwaves.

The plasma generation unit 300 may include a high-frequency power supply 302 and a matching device 304. The high-frequency power supply 302 may supply high-frequency power to any one of an upper electrode and a lower electrode in order to generate a potential difference between the upper electrode and the lower electrode. Here, the upper electrode may be a shower head 310, and the lower electrode may be the substrate support unit 200. The high-frequency power supply 302 may be connected to the lower electrode, and the upper electrode may be grounded.

The shower head 310 may be provided in the chamber 100 so as to vertically oppose the electrostatic chuck 210. The shower head 310 may include a plurality of gas spray holes formed therein to spray gas to the inside of the chamber 100, and may be formed to have a larger diameter than the electrostatic chuck 210. The shower head 310 may be made of a material containing a silicon component or a material containing a metal component.

The gas supply unit 400 may supply gas necessary for the process to the inside of the chamber 100. The gas supply unit 400 may include a gas source 402, a gas supply line 404, and a gas spray nozzle. The gas supply line 404 may connect the gas source 402 to the gas spray nozzle. The gas supply line 404 may supply gas stored in the gas source 402 to the gas spray nozzle. A gas supply valve 406 may be mounted on the gas supply line 404 in order to open and close the passage of the gas supply line 404 or to regulate the amount of fluid flowing through the passage.

Although one gas source 402 and one gas supply valve 406 are illustrated in FIG. 2, the gas supply unit 400 of the present invention may include a plurality of gas sources to supply a plurality of gases to the chamber 100 and a plurality of gas supply valves to independently control supply of the respective gases.

The controller 500 may comprehensively control the operation of the substrate processing apparatus 10 configured as described above. The controller 500 may be, for example, a computer, and may include a central processing unit (CPU), random access memory (RAM), read only memory (ROM), and an auxiliary storage device. The CPU may operate on the basis of a program stored in the ROM or the auxiliary storage device or a process condition to control the overall operation of the substrate processing apparatus 10. In an example, the controller 500 may control the supply operation of various gases by the gas supply unit 400 and the operation of the high-frequency power supply 302 of the plasma generation unit 300. In addition, a computer-readable program necessary for control may be stored in a storage medium. The storage medium may include, for example, a flexible disk, a compact disc (CD), a CD-ROM, a hard disk, a flash memory, a DVD, or the like. The controller 500 may be provided inside or outside the substrate processing apparatus 10. In the case in which the controller 500 is provided outside the substrate processing apparatus 10, the controller 500 may control the substrate processing apparatus 10 using a wired or wireless communication method.

In order to perform the process, the controller 500 according to the embodiment of the present invention may perform control such that gas is supplied to the processing space in the chamber 100 and the supplied gas is converted into plasma by the plasma generation unit 300. In addition, the controller 500 may control the lift pin driving unit 236 to vertically move the lift pins 232 in order to load/unload the substrate W before/after performing the process.

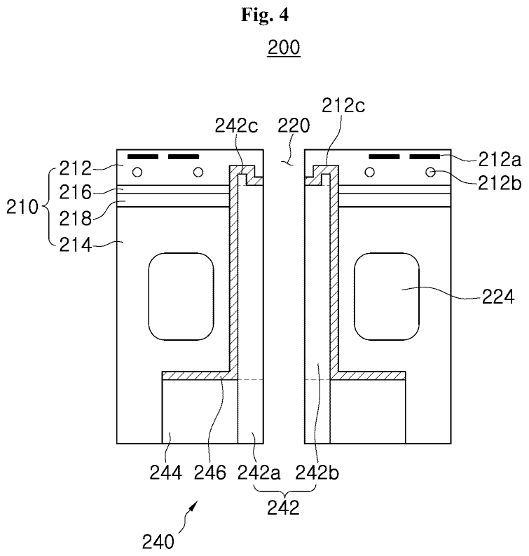

FIG. 4 is a view showing a bush provided in the substrate support unit according to an embodiment of the present invention.

Referring to FIG. 4, the bush 240 according to an embodiment of the present invention may include a first bush 242, a second bush 244, and a bonding layer 246.

The first bush 242 may be provided in the substrate support unit 200, and may be formed in a tube shape. According to the embodiment of the present invention, the first bush 242 may include a lower region 242a, an upper region 242b formed on the lower region 242a, and a protruding portion 242c formed on the upper surface of the upper region 242b. The lower region 242a, the upper region 242b, and the protruding portion 242c of the first bush 242 may be integrally formed with each other. The protruding portion 242c may protrude to a predetermined height in the longitudinal direction of the first bush 242, and the ceramic puck 212 may include a concave portion 212c formed in the lower surface thereof so as to correspond to the protruding portion 242c of the first bush 242 in order to be coupled to the first bush 242.

In this way, in the process of bonding the first bush 242 and the ceramic puck 212 to each other, the protruding portion 242c of the first bush 242 may be fitted into the concave portion 212c in the lower surface of the ceramic puck 212, whereby the first bush 242 and the ceramic puck 212 may be bonded to each other without being misaligned from each other. Accordingly, the first bush 242 and the ceramic puck 212 are integrally coupled to each other in the assembly process thereof, and thus an assembly tolerance may not be generated. In particular, because plasma does not enter an assembly tolerance portion, particles attributable to plasma are not generated, thus leading to improvement in product yield and increase in lifespan of the substrate support unit 200. In addition, because the protruding portion 242c is formed at the first bush 242, the creepage distance of the upper surface of the first bush 242 increases. In more detail, when the ceramic puck 212 and the first bush 242 are coupled to each other, a contact area between the ceramic puck 212 and the first bush 242 increases, and thus coupling between the ceramic puck 212 and the first bush 242 may be enhanced. The first bush 242 according to the embodiment of the present invention may be made of an insulative material, for example, alumina (Al₂O₃). However, this embodiment is not limited thereto.

The second bush 244 may be provided at the lower portion of the first bush 242 and may be coupled to the first bush 242. In more detail, the second bush 244 may be coupled to the base plate 214 and the first bush 242 in a state of being inserted into a recess formed in the lower surface of the base plate 214. According to the embodiment of the present invention, the second bush 244 may be formed in an annular ring shape, and the second bush 244 and the first bush 242 may be coupled to each other in a fit manner. In more detail, the second bush 244 may be coupled to the outer peripheral surface of the lower region 242a of the first bush 242 in a fit manner. Due to such an assembly structure, an assembly tolerance between the first bush 242 and the second bush 244 is reduced. In addition, because the second bush 244 is not in contact with the lift pin 232, damage to the lift pin 232 due to the second bush 244 may be prevented. The second bush 244 according to the embodiment of the present invention may be made of an insulative material, for example, alumina (Al₂O₃). However, this embodiment is not limited thereto.

The bonding layer 246 may be formed in order to bond the first bush 242 and the second bush 244 to the substrate support unit 200. The bonding layer 246 may be formed on the first bush 242 and the upper surface of the second bush 244 coupled to the first bush 242. In more detail, as shown in FIG. 4, the bonding layer 246 may be formed at least on the upper surface of the first bush 242 on which the protruding portion 242c is formed, the outer peripheral surface of the upper region 242b of the first bush 242, and the upper surface of the second bush 244. The first bush 242 may be primarily bonded to the ceramic puck 212 and the base plate 214 by portions of the bonding layer 246 that are formed on the upper surface of the first bush 242 and the outer peripheral surface of the upper region 242b of the first bush 242, and the second bush 244 may be bonded to the base plate 214 by a portion of the bonding layer 246 that is formed on the upper surface of the second bush 244. The bonding layer 246 according to the embodiment of the present invention may be made of silicon, but this embodiment is not limited thereto. In addition, in the embodiment of the present invention, although the adhesive layer 216 of the substrate support unit 200 and the bonding layer 246 are described as being separately provided from each other, this embodiment is not limited thereto. In an example, the adhesive layer 216 provided in the substrate support unit 200 may serve as the bonding layer 246.

As described above, because the bush 240 including the first bush 242 and the second bush 244 is provided in the substrate support unit 200 and the protruding portion 242c is formed at the upper portion of the first bush 242, an assembly tolerance between the substrate support unit 200 and the bush 240 may be reduced. In more detail, because the protruding portion 242c is formed at the upper portion of the first bush 242 and the concave portion 212c corresponding to the protruding portion 242c of the first bush 242 is formed in the ceramic puck 212, the first bush 242 and the ceramic puck 212 may be bonded to each other without being misaligned from each other. Accordingly, an assembly tolerance is not generated between the first bush 242 and the ceramic puck 212, and thus plasma does not enter an assembly tolerance portion, whereby particles are not generated. As a result, product yield may be improved. In addition, the cross-sectional length of the first bush 242 increases due to the protruding portion 242c formed at the first bush 242, and thus a bonding area between the ceramic puck 212 and the first bush 242 increases, with a result that coupling between the ceramic puck 212 and the first bush 242 may be enhanced.

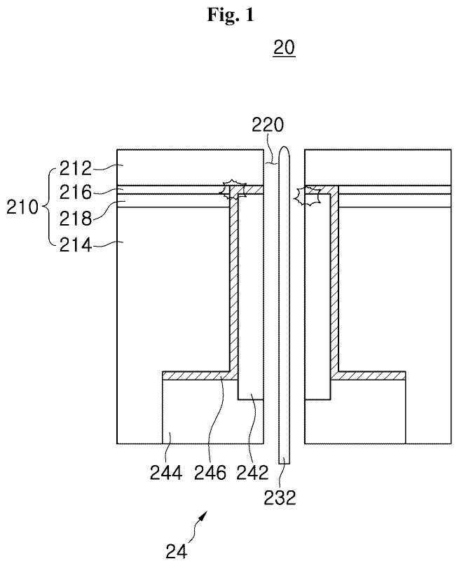

In addition, due to the structure of the bush 240 in which the second bush 244 is not exposed to the pin hole 220 and only the first bush 242 is exposed to the pin hole 220, the possibility of the lift pin 232 being damaged by an assembly tolerance between the first bush 242 and the second bush 244 may be prevented. In the bush structure shown in FIG. 1, because the assembly interface between the first bush 242 and the second bush 244 is exposed to the pin hole 220, an edge of the first bush 242 or the second bush 244 may protrude to the pin hole 220 at the assembly interface depending on an assembly tolerance between the first bush 242 and the second bush 244. This protruding edge of the first bush 242 or the second bush 244 may cause damage to the lift pin 232 ascending and descending through the pin hole 220. In contrast, according to the present invention, because the second bush 244 is not exposed to the pin hole 220 and only the inner surface of the first bush 242 is exposed to the pin hole 220, the possibility of the lift pin 232 being damaged may be prevented.

As is apparent from the above description, according to the present invention, a bush is constituted by a first bush and a second bush, and a protruding portion is formed at the first bush, whereby an assembly tolerance may be reduced when a ceramic puck of a substrate support unit and the bush are bonded to each other.

In addition, since the first bush having the protruding portion and the ceramic puck of the substrate support unit are bonded to each other, a bonding area may be increased, and thus coupling between the bush and the ceramic puck may be enhanced.

The effects achievable through the present invention are not limited to the above-mentioned effects, and other effects not mentioned herein will be clearly understood by those skilled in the art from the above description.

It will be apparent to those skilled in the art that various changes in form and details may be made without departing from the essential characteristics of the invention set forth herein. Accordingly, the above detailed description is not intended to be construed to limit the invention in all aspects and to be considered by way of example. The scope of the invention should be determined by reasonable interpretation of the appended claims and all equivalent modifications made without departing from the invention should be included in the following claims.

What is claimed is:

1. A substrate support unit for supporting a substrate, the substrate support unit including at least one pin hole formed vertically therethrough and accommodating a lift pin therein so as to allow the lift pin to ascend and descend through the at least one pin hole, the substrate support unit comprising:
a ceramic puck configured to allow the substrate to be seated thereon;
a base plate configured to support the ceramic puck;
an adhesive layer for coupling between the ceramic puck and the base plate; and
a bush provided around the at least one pin hole,
wherein the bush comprises:
a first bush having a tube shape; and
a second bush coupled to an outer peripheral surface of the first bush, and
wherein the first bush comprises a protruding portion formed on an upper surface of the first bush.

2. The substrate support unit according to claim 1, wherein the protruding portion protrudes from the upper surface of the first bush to a predetermined height in a longitudinal direction of the first bush, and is coupled to a concave portion formed in a lower surface of the ceramic puck.

3. The substrate support unit according to claim 1, further comprising a bonding layer to couple the bush to the substrate support unit.

4. The substrate support unit according to claim 1, further comprising a coating layer formed between the adhesive layer and the base plate.

5. The substrate support unit according to claim 1, wherein the second bush is coupled to the base plate and the first bush in a state of being inserted into a recess formed in the base plate.

6. The substrate support unit according to claim 1, wherein the second bush is not exposed to the at least one pin hole.

7. The substrate support unit according to claim 1, wherein the first bush comprises a lower region and an upper region formed on the lower region, and
wherein the second bush is coupled to the lower region of the first bush in a fit manner.

8. The substrate support unit according to claim 3, wherein the bonding layer is formed on an upper surface of the first bush, the outer peripheral surface of the first bush, and an upper surface of the second bush coupled to the first bush.

9. A substrate processing apparatus comprising:
a chamber comprising a processing space defined therein;
a substrate support unit disposed in the processing space to support a substrate, the substrate support unit comprising at least one pin hole formed vertically therethrough and accommodating a lift pin therein so as to allow the lift pin to ascend and descend through the at least one pin hole;
a gas supply unit configured to supply gas to the processing space;
a plasma generation unit configured to convert the supplied gas into plasma; and
a controller configured to control the gas supply unit and the plasma generation unit,
wherein the substrate support unit comprises:
a ceramic puck configured to allow the substrate to be seated thereon;
a base plate configured to support the ceramic puck;
an adhesive layer for coupling between the ceramic puck and the base plate; and
a bush provided around the at least one pin hole,
wherein the bush comprises:
a first bush having a tube shape; and
a second bush coupled to an outer peripheral surface of the first bush, and
wherein the first bush comprises a protruding portion formed on an upper surface of the first bush.

10. The substrate processing apparatus according to claim 9, wherein the protruding portion protrudes from the upper surface of the first bush to a predetermined height in a longitudinal direction of the first bush, and is coupled to a concave portion formed in a lower surface of the ceramic puck.

11. The substrate processing apparatus according to claim 9, wherein the substrate support unit further comprises a bonding layer to couple the bush to the substrate support unit.

12. The substrate processing apparatus according to claim 9, further comprising a coating layer formed between the adhesive layer and the base plate.

13. The substrate processing apparatus according to claim 9, wherein the second bush is coupled to the base plate and the first bush in a state of being inserted into a recess formed in the base plate.

14. The substrate processing apparatus according to claim 9, wherein the second bush is not exposed to the at least one pin hole.

15. The substrate processing apparatus according to claim 11, wherein the bonding layer is formed on the upper surface of the first bush, an outer peripheral surface of the first bush, and an upper surface of the second bush coupled to the first bush.

16. A substrate processing apparatus comprising:
a chamber comprising a processing space defined therein;
a substrate support unit disposed in the processing space to support a substrate, the substrate support unit comprising at least one pin hole formed vertically therethrough and accommodating a lift pin therein so as to allow the lift pin to ascend and descend through the at least one pin hole;
a gas supply unit configured to supply gas to the processing space;
a plasma generation unit configured to convert the supplied gas into plasma; and
a controller configured to control the gas supply unit and the plasma generation unit,
wherein the substrate support unit comprises:
a ceramic puck configured to allow the substrate to be seated thereon;
a base plate configured to support the ceramic puck;
an adhesive layer for coupling between the ceramic puck and the base plate; and
a bush provided around the at least one pin hole,
wherein the bush comprises:
a first bush having a tube shape, the first bush being coupled to the ceramic puck, the adhesive layer, and the base plate; and
a second bush coupled to an outer peripheral surface of the first bush and the base plate,
wherein the first bush comprises:
a lower region;
an upper region formed on the lower region; and
a protruding portion formed on an upper surface of the upper region, and
wherein the first bush is integrally coupled to the ceramic puck in such a manner that the protruding portion is inserted into a concave portion formed in a lower surface of the ceramic puck.

17. The substrate processing apparatus according to claim 16, wherein the substrate support unit further comprises a bonding layer to couple the bush to the substrate support unit.

18. The substrate processing apparatus according to claim 16, further comprising a coating layer formed between the adhesive layer and the base plate.

19. The substrate processing apparatus according to claim 16, wherein the second bush is coupled to the base plate and the first bush in a state of being inserted into a recess formed in the base plate.

20. The substrate processing apparatus according to claim 19, wherein the second bush has an annular ring shape, and is coupled to an outer peripheral surface of the lower region of the first bush in a fit manner.
